(19) United States
(12) Patent Application Publication
(10) Pub. No.: US 2014/0297230 A1
(43) Pub. Date: Oct. 2, 2014

(54) SYSTEM AND METHOD FOR HANDLING PLANT ENGINEERING DATA

(71) Applicants: Stephan Grimm, Munich (DE); Sonja Zillner, Munich (DE); Lisa Theresa Abele, Munich (DE)

(72) Inventors: Stephan Grimm, Munich (DE); Sonja Zillner, Munich (DE); Lisa Theresa Abele, Munich (DE)

(73) Assignee: SIEMENS PRODUCT LIFECYCLE MANAGEMENT SOFTWARE INC., Plano, TX (US)

(21) Appl. No.: 14/034,830

(22) Filed: Sep. 24, 2013

(30) Foreign Application Priority Data
Mar. 26, 2013 (EP) 13161091

(51) Int. Cl. G06F 17/50

(52) U.S. Cl. CPC G06F 17/5004
USPC 703/1

(57) ABSTRACT

Methods for modeling a physical facility and corresponding systems and computer-readable mediums. A method includes receiving a plant concept model of a physical facility including a plurality of metamodel entities and receiving a plurality of plant foundational models corresponding to the plant concept model, each plant foundational model addressing a different engineering aspect of the physical facility. The method includes integrating the plurality of plant foundational models and defining a plurality of plant type models each corresponding to a respective plant foundational model. The method includes defining a plurality of plant instance models each corresponding to a respective plant type model and creating an integrated model that provides a user view that combines the plant foundational models and plant instance models. The method includes storing the integrated model.

### CROSS-REFERENCE TO OTHER APPLICATION

This application claims priority to European Patent Application EP13161091, filed Mar. 26, 2013, which is hereby incorporated by reference.

### TECHNICAL FIELD

The present disclosure is directed, in general, to computer-aided design, visualization, and manufacturing systems, product lifecycle management (“PLM”) systems, and similar systems, that manage data for products and other items (collectively, “Product Data Management” systems or PDM systems).

### BACKGROUND OF THE DISCLOSURE

PDM systems manage PLM and other data. Improved systems are desirable.

### SUMMARY OF THE DISCLOSURE

Various disclosed embodiments include systems and methods for modeling a physical facility. A method includes receiving a plant concept model of a physical facility including a plurality of metamodel entities and receiving a plurality of plant foundational models corresponding to the plant concept model, each plant foundational model addressing a different engineering aspect of the physical facility. The method includes integrating the plurality of plant foundational models and defining a plurality of plant type models each corresponding to a respective plant foundational model. The method includes defining a plurality of plant instance models each corresponding to a respective plant type model and creating an integrated model that provides a user view that combines the plant foundational models and plant instance models. The method includes storing the integrated model.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software, or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented;

FIG. 2 illustrates a conceptual model in accordance with disclosed embodiments;

FIG. 3 illustrates plant modeling levels, in accordance with disclosed embodiments;

FIG. 4 illustrates an example of an instantiation of a metamodeling architecture in accordance with disclosed embodiments;

FIG. 5 illustrates a specific example of a plant foundational model created and maintained as described herein in the context of an industrial plant metamodel;

FIG. 6 illustrates a flowchart of a process in accordance with disclosed embodiments; and

FIG. 7 depicts a high-level view of the collaboration infrastructure, models, and metamodels created, stored, and maintained by a system as described herein.

### DETAILED DESCRIPTION

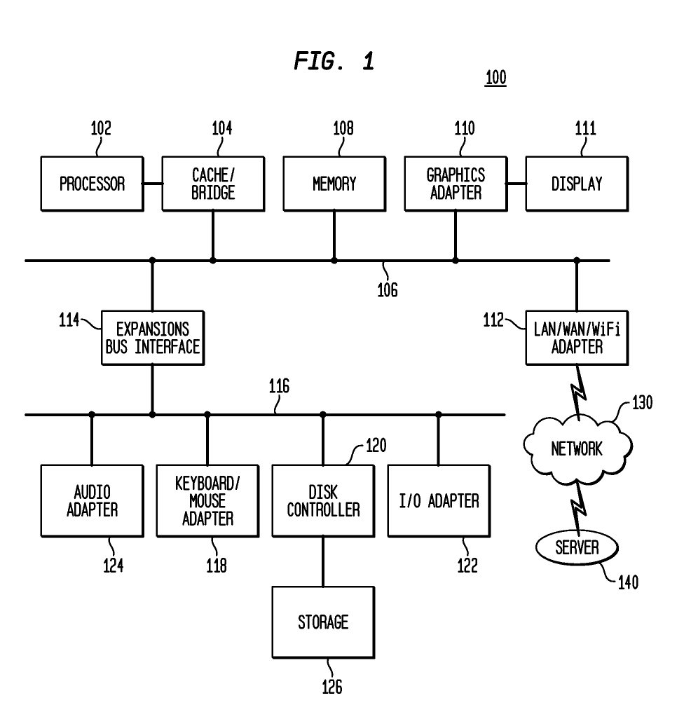

FIGS. 1 through 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

The complex task of planning and engineering an industrial plant involves a multitude of engineers with an expertise in different fields, such as mechanical engineering, electrical engineering, process engineering, software engineering, etc. Each field, and subsets of these fields, may be addressed with specific tools that use proprietary data formats to represent different plant aspects. In such cases, the various tools and standards with incompatible data formats used to model an industrial plant in the context of different engineering disciplines means that there is no single entry point for handling plant models. Further, the involvement of multiple plant engineering experts with different backgrounds in the plant construction process often results in an inconsistent plant model. Current engineering tools do not provide an integrated view on the overall plant, but only on specific parts and aspects of the plant. Moreover, proprietary tools for modeling specific aspects of a plant are typically not very flexible in configuring the user interface for navigation and presentation of plant engineering data.

Engineers typically cope with the large number of different and incompatible tools for plant construction by using them in parallel and manually ensuring consistency between various plant models.

Disclosed embodiments include a combination of metamodels and processes for managing and organizing industrial plant engineering data to enable collaboration, integration, and alignment of plant models that correspond to multiple domain perspectives from various plant engineering experts.

FIG. 1 illustrates a block diagram of a data processing system in which an embodiment can be implemented, for example as a PDM system particularly configured by software or otherwise to perform the processes as described herein, and in particular as each one of a plurality of interconnected and communicating systems as described herein. The data processing system depicted includes a processor 102 connected to a level two cache/bridge 104, which is connected in turn to a local system bus 106. Local system bus 106 may be, for example, a peripheral component interconnect (PCI) architecture bus. Also connected to local system bus in the depicted example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware depicted in FIG. 1 may vary for particular implementations. For example, other peripheral devices, such as an optical disk drive and the like, also may be used in addition or in place of the hardware depicted. The depicted example is provided for the purpose of explanation only and is not meant to imply architectural limitations with respect to the present disclosure.

A data processing system in accordance with an embodiment of the present disclosure includes an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

As described briefly above, disclosed embodiments include a metamodel and corresponding methodology for managing and organizing industrial plant engineering data on collaboration infrastructure to allow for the integration and alignment of multiple domain perspectives from various plant engineering experts.

According to various embodiments, the metamodel determines the knowledge modeling guidelines by describing the most essential building blocks for plant foundational models (entities) and their relationships (e.g. concepts, relationships, attributes, etc.) that are required for capturing the rather complex knowledge of industrial plants. It makes use of a metaobject facility paradigm to utilize several meta layers for instantiating plant foundational model entities. The metamodel is described in more detail below.

The collaboration infrastructure refers to one or more data processing systems that together can handle plant foundational model entities in an information system in terms of storage, visualization, and editing. According to various embodiments, the collaboration infrastructure can include a formal verification mechanism for representing and verifying constraints on plant engineering data and can interlink plant foundational model entities. The collaboration infrastructure can plant foundational model entities and their interlinking in persistent or temporary storage. The collaboration infrastructure can include a visualization component that allows users to visualize plant foundational model entities and navigate their interlinked structure. The collaboration infrastructure can enable collaborative, concurrent editing of plant foundational model entities by several engineers or other users.

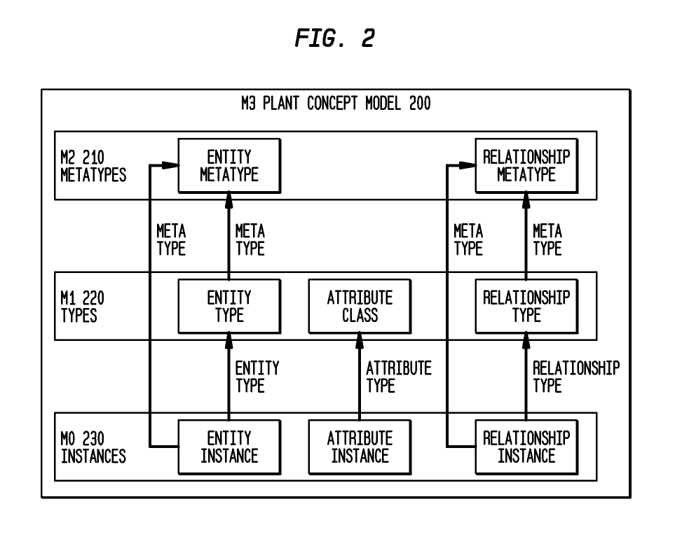

FIG. 2 illustrates a conceptual model in accordance with disclosed embodiments, described in more detail below.

Disclosed embodiments include a conceptual model to provide a way for engineering experts to express knowledge about an industrial plant using the same elements, entities, features, and other aspects to ensure that the individual views and designs are consistent. The main task of this approach is to specify the usage of the disclosed conceptual model to allow for the integration of several partial models defined by various domain experts who use different tools and standards.

Disclosed embodiments use a plurality of modeling “levels” in the conceptual model to model an industrial plant or other facility. In the described example, four levels are used, although more or less could be used in other cases. In an exemplary embodiment discussed below, three different roles of domain experts in the manufacturing areas are considered as target users of the conceptual model, but of course, other implementations could have more or fewer roles.

In this exemplary embodiment, the knowledge engineers specify the partial plant models for various discipline-specific aspects of a plant in collaboration with the engineering experts. The suppliers, such as manufacturers, third party suppliers, or service suppliers, specify abstract information about their equipment, e.g., characteristics of specific machines and other devices. The plant engineers, such as a plant owner, engineering expert or operator, construct, operate, and maintain the plant.

These roles in the plant can be described by using a multilayered metamodel architecture to structure the plant knowledge. Acceptable metamodel architectures are described in several standards, for example, the Meta Object Facility Core Specification 2.0 (2006) defined by the Object Management Group, incorporated by reference herein and referred to herein as the “MOF.” Key modeling concepts of the MOF are type and instance, and the ability to navigate from an instance to its metaobject (its type).

Disclosed embodiments can include multiple levels, described herein as Levels M0-M3. At Level M3, the plant concept model 200 specifies the general elements or features that can be used by the software engineers or other persons to define their (custom) plant foundational models (e.g., a structural model). The three elements used for modeling at this level, in accordance with some disclosed embodiments, are Entity, Relationship, and Attribute.

A “plant concept model,” as used herein, refers to a metamodel that determines the very principle modeling elements required for describing industrial plants conceptually. The main constituents of this model are entities that are connected by relations and that have attributes. These abstract elements are concretized more specifically with respect to certain engineering disciplines in the lower levels, where they become meaningful concepts of plant engineering.

An Entity, as used herein, is an object in an industrial plant that can be classified and has relations to other entities. For example, a structure model can define the entities Hardware Component, Role Class, and Interface.

A Relationship, as used herein, is a specification that connects two or more Entities, the source and the target. Visually, it can be represented as an arrow from the source to the target entity. For example, a relationship used to define a containment hierarchy can be “has part”.

An Attribute, as used herein, is a specification that defines characteristics of an Entity or a Relationship; e.g., a Hardware Component Template can have attributes like “input power=750 kW” and “motor type=asynchronous motor”. Attributes are primarily intended for numbers, quantities, or strings, although other types are permitted. Both Entities and Relationships can have Attributes.

At Level M2 210, the knowledge engineers that specify the (custom) plant foundational models can define, describe, or discuss specific concepts, elements, and terms with experts of different engineering disciplines for a plant foundational model. The resulting model is a metamodel referred to herein as a plant foundational model that can be used by Level M1 220 and Level M0 230. The objects that are used by the authors are called metatypes; e.g., an engineer defines the metatype Hardware Component. While the “authors” described herein are often users, designers, engineers, or other individuals in the relevant fields of expertise, expert systems or other computer systems can act as “authors” in some cases.

A “plant foundational model,” as used herein, refers to a metatype model that captures plant engineering concepts specific for a particular engineering discipline or aspect, such as mechanical engineering or the electrical wiring of a plant. Examples of metatypes in such models are “Hardware Component”, “Power Connection,” or “Plant Operation.” For any engineering discipline or aspect, a specific foundational plant model is being instantiated in alignment to the plant concept model.

At Level M1 220, the suppliers, designers, or other users, e.g., the manufacturers of components, store general information on abstract types in their model, such as specifications of their products in a product catalog. The resulting model of Level M1 220 is referred to herein as a plant type model and used by Level M0 230. For example, “Siemens” describes the Motor Siemens 1FK7 and its specification details in a data sheet.

A “plant type model,” as used herein, refers to a type model that captures concrete types of plant elements, such as motors (as a specific hardware component), “5V power supply cable” (as a specific power connection) or “convey object” (as a specific plant operation).

At Level M0 230, plant engineers can define a concrete industrial plant with instances of the types of level M1. The resulting model is referred to herein as a plant instance model. The plant engineer specifies this model when he installs components of the suppliers in his plant and stores all component-specific information and the relations between the components; e.g., Motor m1 is an instance of Motor Siemens 1FK7.

A “plant instance model,” as used herein, refers to a model of concrete plant components and their interrelation as installed in the physical plant. Characteristic of this model is that all plant-specific operation and installation parameters for components are fixed. For example, for a motor, its serial number, configured maximum speed, or any plant-specific modifications are captured in the plant instance model.

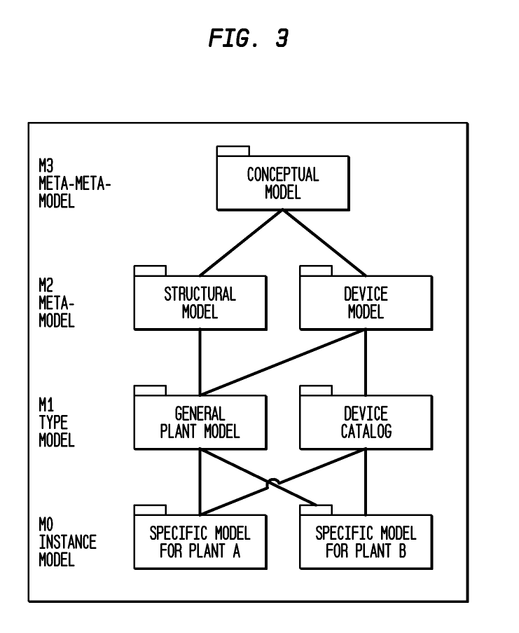

FIG. 3 illustrates plant modeling levels, in accordance with disclosed embodiments, using layers as described in the MOF. The plant concept model described herein can correspond to the M3 layer of the MOF that refers to a meta-meta-model. The plant foundational model described herein, which can include, for example, a structural model and a device model, and other plant foundational models, can correspond to the M2 layer of the MOF that refers to a metamodel. The plant type model described herein, which can include, for example, a general plant model and a device catalog, can correspond to the M1 layer of the MOF that refers to the type model. The plant instance model described herein, which can include, for example, specific models for different plants, can correspond to the M0 layer of the MOF that refers to the instance model.

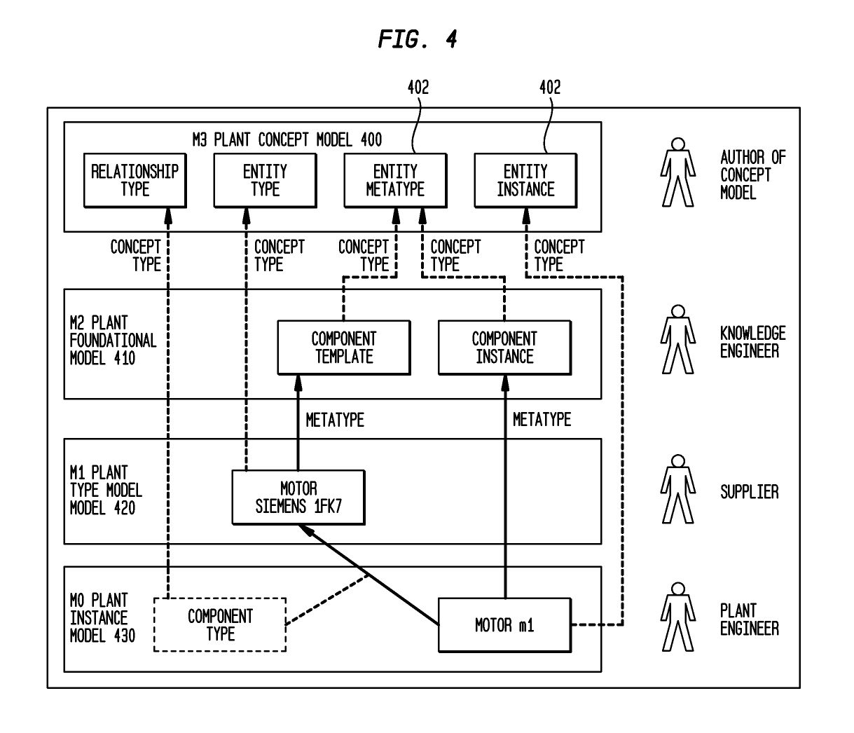

FIG. 4 illustrates an example of a model of a physical facility in accordance with disclosed embodiments. In this example, Level M3 represents a plant concept model 400 that includes a plurality of metamodel entities 402; Level M2 represents a plant foundational model 410; Level M1 represents a plant type model 420; and Level M0 represents a plant instance model 430.

To connect the different levels, relationships between the levels are required. Therefore, the system can define relationships from plant instance model 430 to plant type model 420 such as an entity, attribute, or relationship type and can additionally define a “meta type” relationship that points to the plant foundational model 410. Further, all objects can reference the plant concept model using a “concept type” which can be used to distinguish the different levels.

The advantages of using these modeling levels include a clear separation of the modeling levels to integrate all aspects of the industrial plant provided by the domain experts. Further, connections between the levels can be used to navigate between the levels, e.g., to navigate from a component instance “Motor m1” to its type, and to define constraints on usage and storage of the provided knowledge.

The plant concept model described herein specifies features for several metamodels to provide an integrated view of an entire plant.

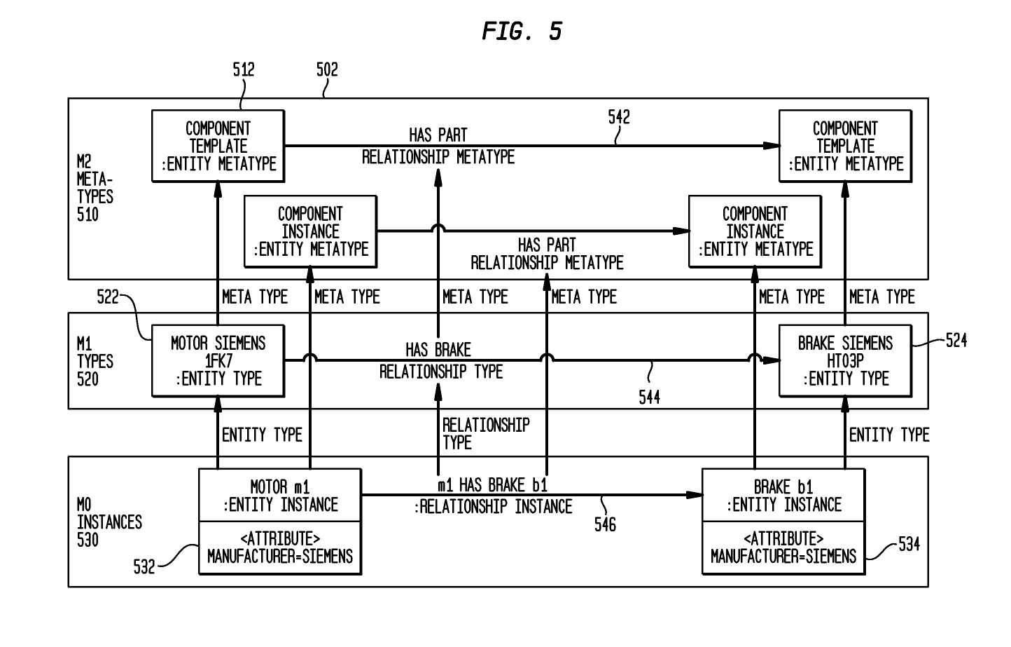

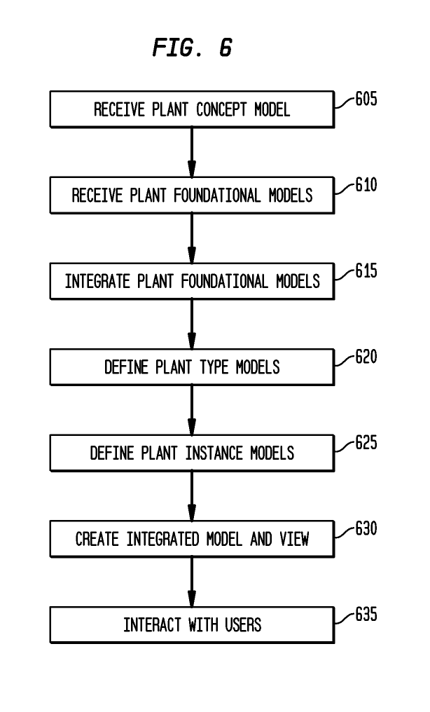

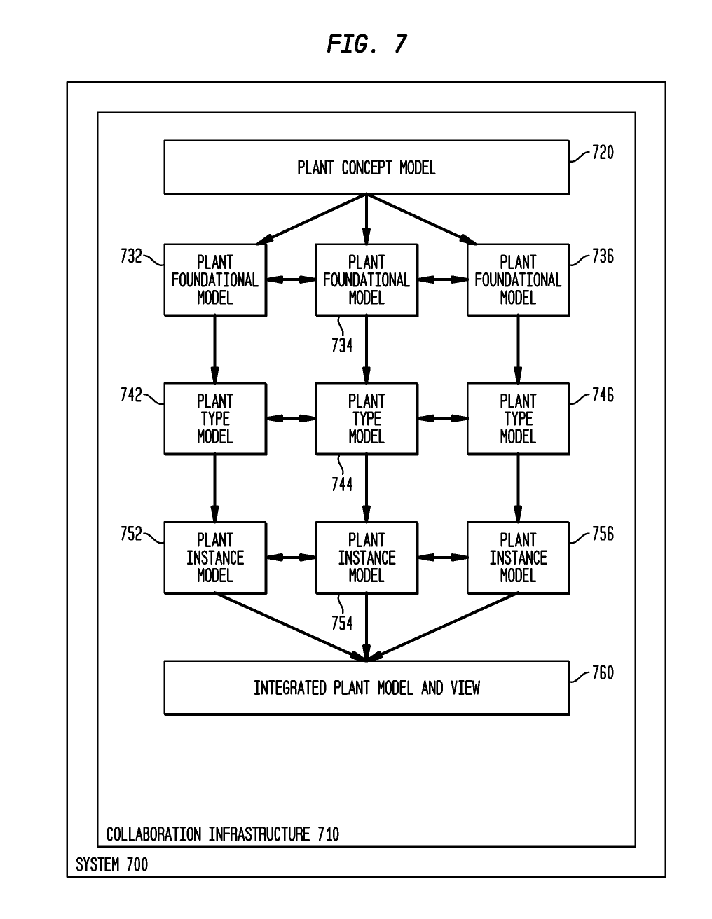

FIG. 5 illustrates a specific example of a plant foundational model created and maintained as described herein in the context of an industrial plant metamodel, used to illustrate the exemplary process of FIG. 6. FIG. 5 illustrates an example for usage of the conceptual model for the structural facets of an industrial plant. FIG. 7 depicts a high-level view of the collaboration infrastructure 710, models, and metamodels created, stored, and maintained by a system 700 as described herein.

FIG. 6 illustrates a flowchart of a process in accordance with disclosed embodiments that may be performed, for example, by one or more PLM or PDM systems, such as data processing system 100, configured to implement a model of a physical facility as described herein, referred to generically as the “system” below. The process illustrated here is described together with features of the various plant models, metamodels, and processes in accordance with various embodiments.

The system receives a plant concept model (605). “Receiving,” as used herein, can include loading from storage, receiving from another device or process, receiving via an interaction with a user, or otherwise. The plant concept model defines the model entities and relationships between the entities for the plant and can correspond to the plant concept model described herein. The plant concept model 720 is stored and maintained by the system 700 as part of the collaboration infrastructure 710. While this particular example is drawn to an industrial plant, the techniques and processes described herein can be applied to any physical facility to be modeled.

The system receives a plurality of plant foundational models (610). Each of the plant foundational models corresponds to the plant concept model and can include entities that each correspond to a metamodel entity defined by the plant concept model. In specific embodiments, this step includes defining plant foundational models that address specific plant engineering aspects or disciplines of the plant as direct instantiations of the plant concept model. The plant foundational models 732/734/736, corresponding to plant concept model 720, are stored and maintained by the system 700 as part of the collaboration infrastructure 710.

Receiving the plant foundational models can include defining and constructing different plant foundational models that correspond to various aspects of an industrial plant, typically via an interaction with the respective expert users, and can be maintained as interlinked in the collaboration infrastructure. The plant foundational models guide the knowledge engineering tasks of the engineers which provide conceptual knowledge of different engineering domains; these domains can include but are not limited to electrical engineering, mechanical engineering, software engineering, etc., so that the plant foundational models are defined and constructed by users to model the physical facility in the context of the respective engineering aspects. The collaboration infrastructure implemented by the system can be used for editing, persisting, browsing, and navigating through the relevant metamodel elements and various plant foundational models. Each of the plant foundational models can be constructed by the engineers or professionals most familiar with the requirements of the respective models.

As described above, the plant foundational models each include a plurality of entities linked by relationships, and at least some of the entities of each of the plant foundational models are linked to corresponding entities of the other plant foundational models. The system can also use a knowledge base to infer relations between various entities, such as identifying that a motor brake must be associated with a motor.

For any domain-specific aspect of an industrial plant, a custom plant foundational model can be received or created to later allow for domain-specific customized navigation in plant engineering data using the navigation and browsing features of the infrastructure. There can be a plant foundational model corresponding to different engineering disciplines or domains, to different design perspectives, to different logical divisions of the plant data, or otherwise. FIG. 5 illustrates a mechanical engineering plant foundational model 502 corresponding to the metamodel or plant concept model. In this example, the Level M2 metatypes 510 (such as plant foundational models described herein) include entity metatypes such as component templates 512. The Level M1 types 520 (such as plant type models described herein) include specific mechanical part types such as a motor 522 and a brake 524. The Level M0 instances 530 (such as plant instance models described herein) include a specific motor instance 532 of the motor type 522 and a specific brake instance 534 of the brake type 524.

The mechanical engineering plant foundational model 502 can also include relationship metatypes such as relationship metatype 542 that describes a type of relationship between the entity metatypes. The mechanical plant foundational model 502 can also include relationship types such as relationship type 544 that describes relationships between the entity types; each of the relationship types can refer to a corresponding relationship metatype. Other plant foundational models can have similar metatypes, types, instances, entities, and relationships.

The author or designer of the specific plant foundational model can interact with the system to define the entity metatypes and connect these with relationship metatypes. The author can define the entity metatypes “Hardware Component Template” and “Hardware Component Instance,” for example. Both entity metatypes can be connected by the relationship metatype “has part,” in this example.

The system can integrate the plurality of plant foundational models (615). This process can include interlinking common aspects of the models; for example, linking the electrical-engineering aspects of a part in the electrical plant foundational model with that part's mechanical-engineering or software-engineering aspects in those respective models, such as linking the electrical-engineering entity for a motor to the mechanical-engineering entity for the same motor. This can include integration of the different engineering disciplines represented by the models. Because each of the plant foundational models can be derived from the plant concept model in a unified way, each of them can be related with each other. This allows for an integrated view of an industrial plant across the respective engineering disciplines when using the infrastructure disclosed herein as a single entry point for browsing and navigating in plant engineering data. In this example, plant foundational models 732/734/736 are linked to each other and integrated as illustrated by the bi-directional arrows. The integrated plant foundational model can be queried, viewed, or otherwise manipulated.

As part of integrating the plant foundational models, the system can validate each plant foundational model for conformity to the plant concept model. The design decisions defined in the plant concept model allow for an automated verification of plant foundational models with regard to their conformity with the plant concept model, such as by using a formal verification mechanism of the infrastructure. For example, the system can automatically highlight any aspect of the plant foundational models that does not conform to meta-model constraints.

The system defines a plant type model corresponding to at least one of the plurality of plant foundational models (620). The plant type model can be an instantiation of a particular plant foundational model. The plant type models 742/744/746, instantiated from respective plant foundational models 732/734/736, are stored and maintained by the system 700 as part of the collaboration infrastructure 710.

The plant foundational models can be used as a basis for modeling plant engineering data in form of plant type models; the plant type models can then serve as templates for concrete plant engineering data descriptions.

As the various plant foundational models have been linked among each other as described above, their instantiation to plant type models inherits this interlinking, reproducing the links and relationships in the plant type models, which provides for an integrated view of various plant engineering aspects in one unifying model when using the infrastructure for persisting of and navigating in plant engineering data as described herein. The instantiation of the interlinked plant foundational models in plant type models ensures a consistent view on the various aspects of an industrial plant covered by the plant foundational models by means of reusing model entities in each view. Using the inherited interlinking, the system can automatically integrate plant type models into an integrated plant type model that can be queried, viewed, or otherwise manipulated.

During the definition of plant type models, the system or user can introduce custom plant description entities, such as particular motor types or other domain-specific class-level entities, which support a customized browsing and navigation in plant foundational models.

The plant concept model can be used as a basis for modeling plant engineering data in the form of the plant type models, which serve as templates for plant instance models. For example, on the type level, a user can define instances of the hardware component templates such as “Siemens Motor 1FK7” and of the Relationship Type “has part” which is detailed and named “has brake”. The system can then verify on Level M0 530 if the instances have the correct “relationship type” as defined by the suppliers on Level M1 520. The plant type models can describe or include information regarding, for example, specific product types, parameters, datasheets, etc.

The system can define plant instance models as instantiations of plant type models (625). In this process, the system instantiates the plant type models as plant instance models that represent the manifestations of plant description elements as they are to be physically implemented, and the plant instance models can be further defined by the system via an interaction with a user who provides specific device data. These plant instance models can, for example, capture plant components and devices, such as a specific motor with a certain serial number as it is assembled in the plant. The plant instance models are stored and maintained by the system. The plant instance models 752/754/756, instantiated from respective plant type models 742/744/746, are stored and maintained by the system 700 as part of the collaboration infrastructure 710.

For example, the entity types of Level M1 520 are instantiated and the entity instances “Motor m1” 532 and “Brake b1” 534 are connected with the more detailed relationship instance 546 “m1 has brake b1”. This reflects the structure of a concrete plant as it is assembled from its components. The plant instance models can also describe or include information regarding specific operational parameters for each instance of a plant type model. For example, for a plant type model entity “motor” that has a range of operating speeds, the plant instance model motor m1 532 may specify “9500 rpm.”

During or after defining the plant instance models, the system can also verify the plant instance models against the plant type models and the plant foundational models. By means of the infrastructure's formal verification mechanisms, instance-level plant engineering data captured in the plant instance models can be checked for consistency against the class level entities and their associated constraints represented in the respective plant type model to ensure a consistent view on plant engineering data.

The system creates an integrated model and view of the plant (630). The integrated model can combine some or all of the plant concept model, plant foundational models, plant type models, and plant instance models. The links and relationships between plant model entities of the plant foundational models, reproduced in the plant type models, can also be inherited by and reproduced in the plant instance models. Using these links and relationships, the system can produce an integrated model and view 760 on concrete plant foundational model entities and their connections. This can be used for navigation in an integrated plant foundational model that spans over various domain-specific plant engineering aspects, using the collaboration infrastructure as a single entry point. For example, electrical wiring information allows an engineer to navigate from a specific motor to its electrically connected power unit or also to a conveyor belt to which it is mechanically connected. The integrated plant model and view 760 is stored and maintained by the system 700 as part of the collaboration infrastructure 710.

The system can thereafter interact with a plurality of users to view, modify, and otherwise manipulate the collaboration infrastructure (635), including the plant concept model, the plant foundational models, the plant type models, the plant instance models, and the integrated plant model and view. The system can perform queries on any entities or models of the infrastructure, such as identifying all motors that operate at a specific speed, entities that satisfy a query at any level of the infrastructure, entities that have specific electrical or mechanical parameters, or otherwise. At each level, the entities can inherit the properties and relations of the corresponding entities at a higher level.

Of course, those of skill in the art will recognize that, unless specifically indicated or required by the sequence of operations, certain steps in the processes described above may be omitted, performed concurrently or sequentially, or performed in a different order.

Disclosed systems and methods establish a representation approach for plant engineering data that can use a plant concept model to formally specify the underlying knowledge modeling principles. The plant concept model inherently provides the guidance for plant engineers to construct plant models in a unified and integrated way such that links between various aspects of a plant are established and preserved.

Disclosed systems and methods also include a plant concept model that is instantiated on an infrastructure and that provides the means for semantic representation, collaborative editing, and integrated navigation on plant engineering data.

Those skilled in the art will recognize that, for simplicity and clarity, the full structure and operation of all data processing systems suitable for use with the present disclosure is not being depicted or described herein. Instead, only so much of a data processing system as is unique to the present disclosure or necessary for an understanding of the present disclosure is depicted and described. The remainder of the construction and operation of data processing system 100 may conform to any of the various current implementations and practices known in the art. The models and metamodels described herein can be stored and managed in one or more data structures maintained by one or more data processing systems described herein, and the processes described with relation to the specific models, particularly but not limited to the processes described with regard to FIG. 6, can be implemented by corresponding use of these data structures.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims. Moreover, none of these claims are intended to invoke paragraph six of 35 USC §112 unless the exact words “means for” are followed by a participle.

What is claimed is:

1. A method for modeling a physical facility, the method performed by at least one data processing system and comprising:
receiving a plant concept model of a physical facility including a plurality of metamodel entities;
receiving a plurality of plant foundational models corresponding to the plant concept model, each plant foundational model addressing a different engineering aspect of the physical facility;
integrating the plurality of plant foundational models;
defining a plurality of plant type models each corresponding to a respective plant foundational model;
defining a plurality of plant instance models each corresponding to a respective plant type model;
creating an integrated model that provides a user view that combines the plant foundational models and plant instance models; and
storing the integrated model.

2. The method of claim 1, wherein the plant foundational models each include a plurality of entities linked by relationships.

3. The method of claim 1, wherein the plant foundational models are defined and constructed by users to model the physical facility in the context of the respective engineering aspects.

4. The method of claim 1, wherein integrating the plurality of plant foundational models includes linking entities of each of the plant foundational models to corresponding entities of the other plant foundational models.

5. The method of claim 1, wherein each of the plant foundational models is created from an instantiation of the plant concept model, each of the plant type models is created from an instantiation of a plant foundational model, and each of the plant instance models is created from an instantiation of a plant type model.

6. The method of claim 1, wherein links and relationships between entities are inherited from the plant foundational models by the plant type models.

7. The method of claim 1, wherein a user can interact with a collaboration infrastructure to manipulate and view the plant concept model, the plant foundational models, the plant type models, the plant instance models, and the integrated plant model.

8. At least one data processing system comprising:
a processor; and
an accessible memory, the data processing system particularly configured to
receive a plant concept model of a physical facility including a plurality of metamodel entities;
receive a plurality of plant foundational models corresponding to the plant concept model, each plant foundational model addressing a different engineering aspect of the physical facility;
integrate the plurality of plant foundational models;
define a plurality of plant type models each corresponding to a respective plant foundational model;
define a plurality of plant instance models each corresponding to a respective plant type model;
create an integrated model that provides a user view that combines the plant foundational models and plant instance models; and
store the integrated model.

9. The data processing system of claim 8, wherein the plant foundational models each include a plurality of entities linked by relationships.

10. The data processing system of claim 8, wherein the plant foundational models are defined and constructed by users to model the physical facility in the context of the respective engineering aspects.

11. The data processing system of claim 8, wherein integrating the plurality of plant foundational models includes linking entities of each of the plant foundational models to corresponding entities of the other plant foundational models.

12. The data processing system of claim 8, wherein each of the plant foundational models is created from an instantiation of the plant concept model, each of the plant type models is created from an instantiation of a plant foundational model, and each of the plant instance models is created from an instantiation of a plant type model.

13. The data processing system of claim 8, wherein links and relationships between entities are inherited from the plant foundational models by the plant type models.

14. The data processing system of claim 8, wherein a user can interact with a collaboration infrastructure to manipulate and view the plant concept model, the plant foundational models, the plant type models, the plant instance models, and the integrated plant model.

15. A non-transitory computer-readable medium encoded with executable instructions that, when executed, cause one or more data processing systems to:
receive a plant concept model of a physical facility including a plurality of metamodel entities;
receive a plurality of plant foundational models corresponding to the plant concept model, each plant foundational model addressing a different engineering aspect of the physical facility;
integrate the plurality of plant foundational models;
define a plurality of plant type models each corresponding to a respective plant foundational model;
define a plurality of plant instance models each corresponding to a respective plant type model;
create an integrated model that provides a user view that combines the plant foundational models and plant instance models; and
store the integrated model.

16. The computer-readable medium of claim 15, wherein the plant foundational models each include a plurality of entities linked by relationships.

17. The computer-readable medium of claim 15, wherein the plant foundational models are defined and constructed by users to model the physical facility in the context of the respective engineering aspects.

18. The computer-readable medium of claim 15, wherein integrating the plurality of plant foundational models includes linking entities of each of the plant foundational models to corresponding entities of the other plant foundational models.

19. The computer-readable medium of claim 15, wherein each of the plant foundational models is created from an instantiation of the plant concept model, each of the plant type models is created from an instantiation of a plant foundational model, and each of the plant instance models is created from an instantiation of a plant type model.

20. The computer-readable medium of claim 15, wherein links and relationships between entities are inherited from the plant foundational models by the plant type models.
